(19) United States
(12) Patent Application Publication
(10) Pub. No.: US 2020/0035535 A1
(43) Pub. Date: Jan. 30, 2020

(54) METAL BONDED ELECTROSTATIC CHUCK FOR HIGH POWER APPLICATION

(71) Applicant: Applied Materials, Inc., Santa Clara, CA (US)

(72) Inventor: Vijay D. PARKHE, San Jose, CA (US)

(21) Appl. No.: 16/047,641

(22) Filed: Jul. 27, 2018

(51) Int. Cl. H01L 21/683; H01J 37/32

(52) U.S. Cl. CPC H01L 21/6833; H01J 2237/334; H01J 37/32458; H01J 37/32724

(57) ABSTRACT

Implementations described herein provide a substrate support assembly which provides longevity and good heat transfer. The substrate support assembly has an electrostatic chuck having a workpiece supporting surface and a bottom surface, a cooling base having a top surface and a bonding layer securing the bottom surface of the electrostatic chuck and the top surface of the cooling base. The bonding layer includes a layer of metal.

### BACKGROUND

### Field

Implementations described herein generally relate to semiconductor manufacturing and more particularly to a substrate support assembly having a metal bonded electrostatic chuck.

### Description of the Related Art

Reliably producing nanometer and smaller features is one of the key technology challenges for next generation very large scale integration (VLSI) and ultra-large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

To drive down manufacturing cost, integrated chip (IC) manufactures demand higher throughput and better device yield and performance from every silicon substrate processed. Some fabrication techniques being explored for next generation devices under current development require processing at temperatures above 300 degrees Celsius and high bias power while processing films on a substrate. The high bias power improves the film roughness and morphology on the substrate. However, the high bias power also provides heat energy when the power is on.

Some of these high temperature and high power fabrication techniques are performed in processing chambers that utilize electrostatic chucks to secure a substrate being processed within the chamber. Conventional electrostatic chucks are part of a substrate support assembly that includes a cooling plate. The cooling plate is bonded to the electrostatic chuck. The material utilized for the bond between the cooling plate and electrostatic chuck is sensitive to high temperature, thermal expansion, and high energy fields. The conventional electrostatic chucks may experience problems with the bonding material due to a combination of the aforementioned factors. For example, the bond material may delaminate and fail altogether, causing a loss of vacuum or movement in the substrate support. The processing chamber must be taken off-line in order to replace electrostatic chucks having problems with the bonding material, thus undesirably increasing costs, while reducing processing yield.

Thus, there is a need for an improved substrate support assembly suitable for use with high power electrostatic chucks.

### SUMMARY

Implementations described herein provide a substrate support assembly which provides longevity and good heat transfer. The substrate support assembly has an electrostatic chuck having a workpiece supporting surface and a bottom surface, a cooling base having a top surface, and a bonding layer securing the bottom surface of the electrostatic chuck and the top surface of the cooling base. The bonding layer includes a layer comprised of a metal or metal compound.

In another implementation, a processing chamber is provided. The processing chamber has a body having walls and a lid defining an interior processing region. A substrate support assembly is disposed in the interior processing region. The substrate support assembly has an electrostatic chuck having a workpiece supporting surface and a bottom surface, a cooling base having a top surface and a bonding layer securing the bottom surface of the electrostatic chuck and the top surface of the cooling base. The bonding layer includes a layer comprised of a metal or metal compound.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 is a cross-sectional schematic side view of a processing chamber having one embodiment of a substrate support assembly.

FIG. 2 is a schematic partial side view of the substrate support assembly detailing one embodiment of a metal-containing layer bonding an electrostatic substrate support and a cooling base.

FIG. 3 is a schematic partial side view of the substrate support assembly detailing another embodiment of a metal-containing layer bonding an electrostatic substrate support and a cooling base.

FIG. 4 is a schematic partial side view of the substrate support assembly detailing yet another embodiment of a metal-containing layer bonding an electrostatic substrate support and a cooling base.

FIG. 5 is a schematic partial side view of the substrate support assembly detailing yet another embodiment of a metal-containing layer bonding an electrostatic substrate support and a cooling base.

FIG. 6 is a schematic partial side view of the substrate support assembly detailing yet another embodiment of a metal-containing layer bonding an electrostatic substrate support and a cooling base.

FIG. 7 is a schematic partial side view of the substrate support assembly detailing yet another embodiment of a metal-containing layer bonding an electrostatic substrate support to a powered cooling base.

FIG. 8 is a schematic partial side view of the substrate support assembly detailing yet another embodiment of a metal-containing layer bonding an electrostatic substrate support having a powered cooling base.

To facilitate understanding, identical reference numerals have been used, where possible, to designate identical elements that are common to the figures. It is contemplated that elements disclosed in one implementation may be beneficially used in other implementations without specific recitation.

### DETAILED DESCRIPTION

Implementations described herein provide a substrate support assembly which enables a low to high temperature operation of an electrostatic chuck (ESC). High temperature is intended to refer to temperatures in excess of about 150 degrees Celsius, for example, temperatures in excess of about 250 degrees Celsius, such as temperatures of about 250 degrees Celsius to about 300 degrees Celsius. The substrate support assembly includes a cooling plate that is bonded to the electrostatic chuck by a bonding layer. The bonding layer is formed from several distinct layers that enable operation of the electrostatic chuck at range of temperatures, including the high temperatures described above. At least one of the distinct layers is a metal-containing layer that is comprised of a metal or metal compound. The function of the metal-containing layer in the bonding layer varies as the embodiments range from a low temperature configuration to a high temperature configuration. The purpose of metal bond provided by the metal-containing layer for the low temperature configuration is to provide good heat transfer from the ESC to the cooling base disposed thereunder. The purpose of metal bond provided by the metal-containing layer comprising the bonding layer for high temperature configuration is to mechanically hold the cooling base to the ESC. A thermal gasket is utilized between a molybdenum layer and the cooling plate for handling the temperature drop therebetween.

Although the substrate support assembly is described below in an etch processing chamber, the substrate support assembly may be utilized in other types of plasma processing chambers, such as physical vapor deposition chambers, chemical vapor deposition chambers, ion implantation chambers, among others, and other systems where high temperature (i.e., temperatures exceeding 150 degrees) processing occurs.

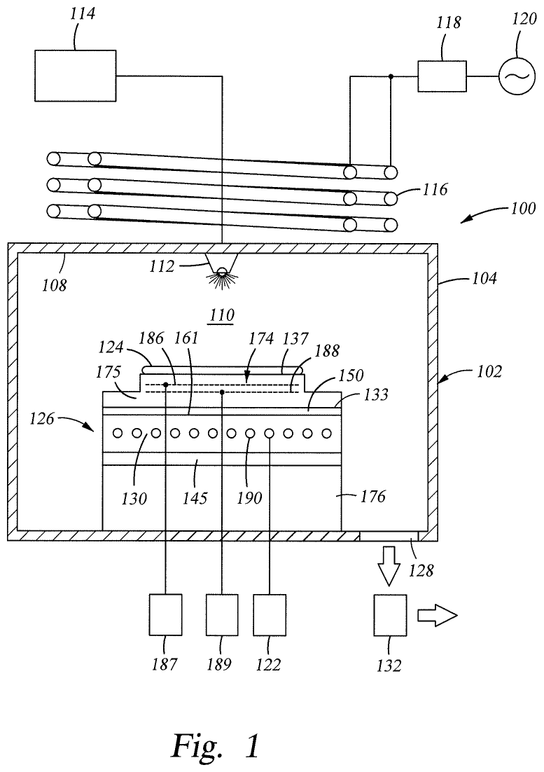

FIG. 1 is a cross-sectional schematic view of an exemplary plasma processing chamber 100, shown configured as an etch chamber, having a substrate support assembly 126. The substrate support assembly 126 may be utilized in other types of processing plasma chambers, for example plasma treatment chambers, annealing chambers, physical vapor deposition chambers, chemical vapor deposition chambers, and ion implantation chambers, among others, as well as other systems where the ability to control processing uniformity for a surface or workpiece, such as a substrate, is desirable. Control of the dielectric properties tan(δ), i.e., dielectric loss, or ρ, i.e., the volume resistivity at elevated temperature ranges for the substrate support assembly 126 beneficially enables azimuthal processing control, i.e., processing uniformity, for a substrate 124 disposed thereon the substrate support assembly 126.

The plasma processing chamber 100 includes a chamber body 102 having sidewalls 104, a bottom and a lid 108 that enclose an interior processing region 110. An injection apparatus 112 is coupled to the sidewalls 104 and/or lid 108 of the chamber body 102. A gas panel 114 is coupled to the injection apparatus 112 to allow process gases to be provided into the processing region 110. The injection apparatus 112 may be one or more nozzle or inlet ports, or alternatively a showerhead. Processing gas, along with any processing by-products, are removed from the processing region 110 through an exhaust port 128 formed in the sidewalls 104 or bottom 106 of the chamber body 102. The exhaust port 128 is coupled to a pumping system 132, which includes throttle valves and pumps utilized to control the vacuum levels within the processing region 110.

The processing gas may be energized to form a plasma within the processing region 110. The processing gas may be energized by capacitively or inductively coupling RF power to the processing gases. In the embodiment depicted in FIG. 1, a plurality of coils 116 are disposed above the lid 108 of the plasma processing chamber 100 and coupled through a matching circuit 118 to an RF power source 120.

The substrate support assembly 126 is disposed in the processing region 110 below the injection apparatus 112. The substrate support assembly 126 includes an electrostatic chuck (ESC) 174 and a cooling base 130. The cooling base 130 is supported by a base plate 176. The base plate 176 is supported by one of the sidewalls 104 or bottom 106 of the processing chamber. The substrate support assembly 126 may additionally include a heater assembly (not shown). Additionally, the substrate support assembly 126 may include a facility plate 145 and/or an insulator plate (not shown) disposed between the cooling base 130 and the base plate 176 to facilitate electrical, cooling, and gas connections with the substrate support assembly 126.

The cooling base 130 is formed from a metal material or other suitable material. For example, the cooling base 130 may be formed from aluminum (Al). The cooling base 130 includes cooling channels 190 formed therein. The cooling channels 190 are connected to a heat transfer fluid source 122. The heat transfer fluid source 122 provides a heat transfer fluid, such as a liquid, gas or combination thereof, which is circulated through one or more cooling channels 190 disposed in the cooling base 130. The fluid flowing through neighboring cooling channels 190 may be isolated to enabling local control of the heat transfer between the ESC 174 and different regions of the cooling base 130, which assists in controlling the lateral temperature profile of the substrate 124. In one embodiment, the heat transfer fluid circulating through the cooling channels 190 of the cooling base 130 maintains the cooling base 130 at a temperature between about 90 degrees Celsius and about 80 degrees Celsius or at a temperature lower than 90 degrees Celsius.

The ESC 174 includes one or more chucking electrodes 186 disposed in a dielectric body 175. The dielectric body 175 has a workpiece support surface 137 and a bottom surface 133 opposite the workpiece support surface 137. The dielectric body 175 of the ESC 174 is fabricated from a ceramic material, such as alumina (Al₂O₃), aluminum nitride (AlN) or other suitable material. Alternately, the dielectric body 175 may be fabricated from a polymer, such as polyimide, polyetheretherketone, polyaryletherketone and the like.

The dielectric body 175 optionally includes one or more resistive heaters 188 embedded therein. The resistive heaters 188 are utilized to elevate the temperature of the substrate support assembly 126 to a temperature suitable for processing a substrate 124 disposed on the workpiece support surface 137 of the substrate support assembly 126. The resistive heaters 188 are coupled through the facility plate 145 to a heater power source 189. The heater power source 189 may provide 900 watts or more power to the resistive heaters 188. A controller (not shown) is utilized control the operation of the heater power source 189, which is generally set to heat the substrate 124 to a predefined temperature. In one embodiment, the resistive heaters 188 include a plurality of laterally separated heating zones, wherein the controller enables at least one zone of the resistive heaters 188 to be preferentially heated relative to the resistive heaters 188 located in one or more of the other zones. For example, the resistive heaters 188 may be arranged concentrically in a plurality of separated heating zones. The resistive heaters 188 may maintain the substrate 124 at a temperature suitable for processing, such as between about 180 degrees Celsius to about 500 degrees Celsius, such as greater than about 250 degrees Celsius, such as between about 250 degrees Celsius and about 300 degrees Celsius.

The ESC 174 generally includes a chucking electrode 186 embedded in the dielectric body 175. The chucking electrode 186 may be configured as a mono polar or bipolar electrode, or other suitable arrangement. The chucking electrode 186 is coupled through an RF filter to a chucking power source 187, which provides a DC power to electrostatically secure the substrate 124 to the workpiece support surface 137 of the ESC 174. The RF filter prevents RF power utilized to form a plasma (not shown) within the plasma processing chamber 100 from damaging electrical equipment or presenting an electrical hazard outside the chamber.

The workpiece support surface 137 of the ESC 174 includes gas passages (not shown) for providing backside heat transfer gas to the interstitial space defined between the substrate 124 and the workpiece support surface 137 of the ESC 174. The ESC 174 also includes lift pin holes for accommodating lift pins (not shown) for elevating the substrate 124 above the workpiece support surface 137 of the ESC 174 to facilitate robotic transfer into and out of the plasma processing chamber 100.

A bonding layer 150 is disposed below the ESC 174 and secures the ESC 174 to the cooling base 130. In other embodiments, the bonding layer 150 is disposed between the ESC 174 and a lower plate that is disposed between the ESC 174 and cooling base 130, as will be described further below. The bonding layer 150 may have a thermal conductivity between about 0.1 W/mK and about 5 W/mk. The bonding layer 150 may be formed from several layers which compensate for different thermal expansion between the ESC 174 and underlying portions of the substrate support assembly 126, such as for example, the cooling base 130. The layers comprising the bonding layer 150 may be formed from different materials and is discussed in reference to subsequent figures illustrating separate embodiments.

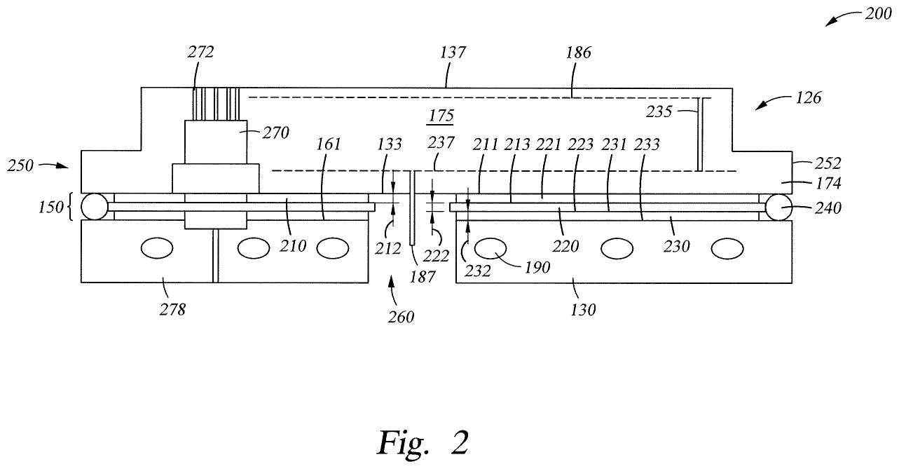

FIG. 2 is a partial schematic side view of the substrate support assembly 200 detailing one embodiment of the bonding layer 150 disposed between an electrostatic chuck (ESC) 174 and the cooling base 130. The ESC 174 may be a high power chuck without heaters and having the chucking electrode 286 electrically coupled to a lower chucking electrode 237 via a connector 235. An electrical socket 260 provides connections from the chucking power source 187 to the chucking electrodes 286, 237 embedded in the dielectric body 175. The electrical socket 260 may extend through the bonding layer 150 and the cooling base 130 or alternatively, couple to a corresponding connector (not shown) in the substrate support assembly 200.

A porous plug 270 may be disposed in the substrate support assembly 200. For example, the porous plug 270 may be disposed in at least one of the ESC 174 and the cooling base 130. The porous plug 270 is coupled to a backside gas source, which is not shown. The porous plug 270 may function to control the rate of gas passing to the workpiece support surface 137 of the ESC 174, or to prevent arcing within the gas passages of the substrate support assembly 200. A plurality of gas ports 272 are coupled to the porous plug 270 and extend through the workpiece support surface 137. Backside gas may be supplied from the backside gas source into the porous plug 270 and out the gas ports 272 during processing operations of a substrate disposed thereon the workpiece support surface 137. The backside gas along with the cooling base 130 helps to maintain the temperature of the substrate disposed on the ESC 174 during processing operations.

The cooling base 130 is secured to the ESC 174 by the bonding layer 150 disposed therebetween. The bonding layer 150 can withstand a temperature gradient of about 60 degrees Celsius between the bottom surface 133 of the ESC 174 and the top surface 161 of the cooling base 130. The bonding layer 150 may extend to about an outer diameter 252 of the ESC 174 and the cooling base 130. The bonding layer 150 is flexible to account for the high RF power provided to the ESC 174 and prevents delamination or the breaking free of the bond between the ESC 174 and the cooling base 130.

The bonding layer 150 comprises two or more material layers. At least one of the layers of the bonding layer 150 a metal-containing layer that is fabricated from a metal or metal alloy. In one embodiment, the bonding layer 150 includes a first layer 210, a second layer 220, and a third layer 230. The first layer 210, second layer 220, and third layer 230 may have an outer periphery 250. The bonding layer 150 may optionally include one or more o-rings, such as o-ring 240. The o-ring 240 is disposed along the outer diameter 252 of the ESC 174. The o-ring 240 is sized to sealingly abut the ESC 174 and cooling base 130, thus isolating the bonding layer 150 from the interior processing volume of the processing chamber.

The o-ring 240 may be formed from a perfluoro elastomer material or other suitable material. For example, the material of the o-ring 240 may be formed from a perfluoroelastomer, or a cross-linked polyethylene. The material of the o-ring 240 may have a sufficiently soft Shore A hardness of about 70 durometers for making a vacuum seal. The o-ring 240 forms a vacuum tight seal between the ESC 174 and the cooling base 130. The vacuum tight seal formed by the o-ring 240 may prevent the loss of the vacuum for the process environment through the substrate support assembly 126. Additionally, the o-ring 240 may protect the inner portions of the substrate support assembly 126 from exposure to the plasma environment. That is, the o-ring 240 protects the first layer 210, second layer 220, and third layer 230 of the bonding layer 150 from exposure to the plasma formed within the processing volume of the processing chamber. The o-ring 240 may additionally prevent volatized gases originating from the first layer 210, second layer 220, and third layer 230 from contaminating the plasma environment, and ultimately the substrate. Alternately, the first layer 210, second layer 220, and third layer 230 are bonded with the ESC 174 and cooling base 130 and form a vacuum seal without the use of an o-ring.

The first layer 210 of the bonding layer 150 may have a top surface 211 and a bottom surface 213. The top surface 211 is in contact with the bottom surface 133 of the ESC 174. The top surface 211 of the first layer 210 may be at a temperature of the bottom surface 133 of the ESC 174, i.e., about 60 degrees Celsius to about 300 degrees Celsius. To accommodate the high power and temperature of the electrostatic chuck, the first layer 210 may be fabricated from a material having an operating temperature that exceeds 150 degrees Celsius.

The first layer 210 may be formed in sheets. The first layer 210 may have a thickness 212 minimized to enhance thermal conductivity. In one embodiment, the first layer 210 may be a perfluoro polymer bonding agent, i.e., an adhesive material. The first layer 210 may have a thermal conductivity selected in a range from 0.1 to 0.5 W/mK that is suitable for high processing temperatures.

The second layer 220 is separated from the ESC 174 by the first layer 210. The separation from the ESC 174 enables the second layer 220 to have an operating temperate that is less than that of the first layer 210. The second layer 220 may have a top surface 221 and a bottom surface 223. The top surface 221 of the second layer 220 contacts the bottom surface 213 of the first layer 210. The top surface 221 may form a bond with the bottom surface 213 of the first layer 210. The bottom surface 223 of the second layer 220 may be in contact with the third layer 230. The second layer 220 forms a bond with the bottom surface 213 of the first layer 210 and the second layer 220. In one example, the second layer 220 is a metal containing layer. The second layer 220 may be formed from a metal such as Al, AlSiC or other suitable high temperature material. The second layer 220 may have a thickness 222 minimized to enhance thermal conductivity.

The third layer 230 is separated from the high temperature of the ESC 174 by the first and second layers 210, 220. Thus, the third layer 230 may have an operating temperate less than that of the second layer 220. The third layer 230 may have a top surface 231 and a bottom surface 233. The third layer 230 may be disposed between the second layer 220 and the cooling base 130. The top surface 231 of the third layer 230 is bonded to the bottom surface 223 of the second layer 220 and the bottom surface 233 of the third layer 230 is bonded to the cooling base 130. The bottom surface 233 of the third layer may be at a temperature of the cooling base 130, i.e., between about 80 degrees Celsius and about 60 degrees Celsius. In one embodiment, the third layer 230 forms a low temperature bonding layer with the cooling base 130.

The third layer 230 may be formed from perfluoro compound, silicone, porous graphite or an acrylic compound or other suitable material. For example, the first layer 210 and third layer 230 may be formed from perfluoropolymer, a flexible graphite material, or polymide. The perfluoro compounds are extremely stabile conferring high thermal and chemical stability, adhere well to ceramics, are not rigid, have minimal compression, and have the ability to withstand considerable strain. The first layer 210 and third layer 230 are configured to thermally expand with the expansion of the ESC 174 and cooling base 130, while withstanding high RF energy.

In one example, the first layer 210 and third layer 230 of the bonding layer 150 are formed from a perfluoro polymer material, and sandwich the second layer 220, a metal containing layer, that is formed from a metal or metal alloy, such as an alloy of aluminum. The second layer 220 is an Al alloy, such as aluminum nitride (AlN), selected to provide a relatively high thermal conductivity for an electrically insulating ceramic (70-210 W/(m·K) for polycrystalline material, and as high as 285 W/(m·K) for single crystals). Thus, the metal-containing layer, i.e., the metal or metal compound of the second layer 220 for the bonding layer 150, provides good heat transfer from ceramic of the ESC 174 to cooling base 130.

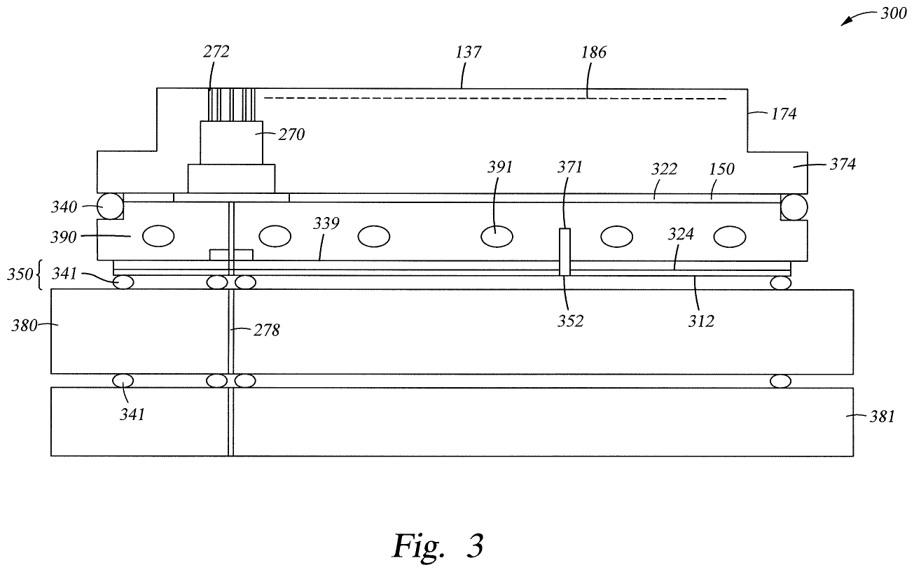

FIG. 3 is a schematic side view of the substrate support assembly 300 detailing another embodiment of the bonding layer 150 having metal therein disposed between an electrostatic chuck 374 and the cooling base 390. The ESC 374 may be a high power chuck without heaters and having the chucking electrode 186. The ESC 374 may be disposed on the cooling base 130. The cooling base 130 may be disposed on an insulative base 380. The insulative base 380 may be disposed on a mounting base 381. The mounting base 381 may formed from aluminum, aluminum alloy or other suitable material. The ESC 374, cooling base 130, insulative base 380 and mounting base 381 may be coupled together.

A first bonding layer 322 may be formed between the cooling base 130 and the ESC 374. The first bonding layer 322 may be formed from Al, Al₂O₃ or AlSiC. The first bonding layer 322 may have a thickness extending perpendicularly between the ESC 374 and the cooling base 130. The thickness may be between about 0.2 inches and about 0.1 inches.

The first bonding layer 322 may be surrounded by an O-ring 340 to protect the first bonding layer 322 from exposure to the aggressive plasma environment in the process chamber. The O-ring 340 may be formed from a perfluoro polymer with or without inorganic material such as SiC, a cross-linked polyethylene, or a perfluoroelastomer, among other suitable materials.

A plurality of O-rings 341 is optionally disposed between the cooling base 130 and the insulative base 380. Similarly, the O-rings 341 are optionally disposed between the insulative base 380 and the mounting base 381. The O-rings 341 seal the gas passage 278 to prevent backside gas from escaping therefrom when the backside gas is provided to the gas ports 272. The O-rings 341 additionally provide a seal for preventing the chamber from losing vacuum through the substrate support assembly 126. The O-rings 341 may be formed from a perfluoro polymer with or without inorganic material such as SiC, a cross-linked polyethylene, or a perfluoroelastomer, among other suitable materials.

A second bonding layer 350 is disposed between the cooling base 130 and the insulative base 380. The insulative base 380 may be a thermoset, rigid and translucent plastic. The insulative base 380 is formed from a polystyrene material, such as a polyimide material, a high-performance polyimide-based plastic, or polystyrene cross linked with divinylbenzene, or other suitable plastic. The insulative base 380 has a thermal coefficient of expansion between about 3.0×10⁻⁵/C and about 5×10⁻⁵/C. The insulative base 380 has a thermal conductivity of about 0.2 W/mK to about 1.8 W/mK. In one embodiment, the insulative base 380 is formed from polystyrene cross linked with divinylbenzene.

The second bonding layer 350 may additionally include a first sheet 324 and a second sheet 312. The second bonding layer 350 has a thickness extending perpendicularly from the cooling base 130. The thickness may be between about 0.20 inches and about 0.05 inches.

The first sheet 324 is disposed on a bottom surface 339 of the cooling base 130. The first sheet 324 may be formed from perfluoropolymer, a flexible graphite, or polymide.

The second sheet 312 is disposed between the first sheet 324 and the insulative base 380. The second sheet 312 may be formed from a metal material such as Al, Al₂O₃ or AlSiC, molybdenum alloy, AlSi alloy or aluminum alloy which is bonded with the first sheet 324. For example, the first sheet 324 and second sheet 312 are diffusion bonded under pressure and temperature while in a vacuum. Diffusion bonding is capable of joining similar and dissimilar metals alike. In diffusion bonding, the atoms of the two metallic surfaces intersperse between the surfaces over time. This is accomplished at elevated temperatures and by applying high contact pressure to press the first sheet 324 and the second sheet 312 together and, thus, bonding the sheets together. In one embodiment, the bond between the second sheet 312 and first sheet 324 is performed in a contact pressure range between about 100 psi and about 300 psi and at a temperature range between about 500 Celsius and about 600 Celsius.

The second bonding layer 350 may include a mechanical fastener 352 which mates with a receiving socket 371 disposed in the cooling base 130. In one embodiment, the mechanical fastener 352 is a threaded fastener and the receiving socket 371 is a tapped hole or threaded insert, such as a HELICOIL® type threaded insert. Alternately, the mechanical fastener 352 may be a bolt, a press fit pin, a rivet, or other suitable fastener. The mechanical fastener 352 ensures the connection between the second bonding layer 350 and the cooling base 130 is secure yet removable.

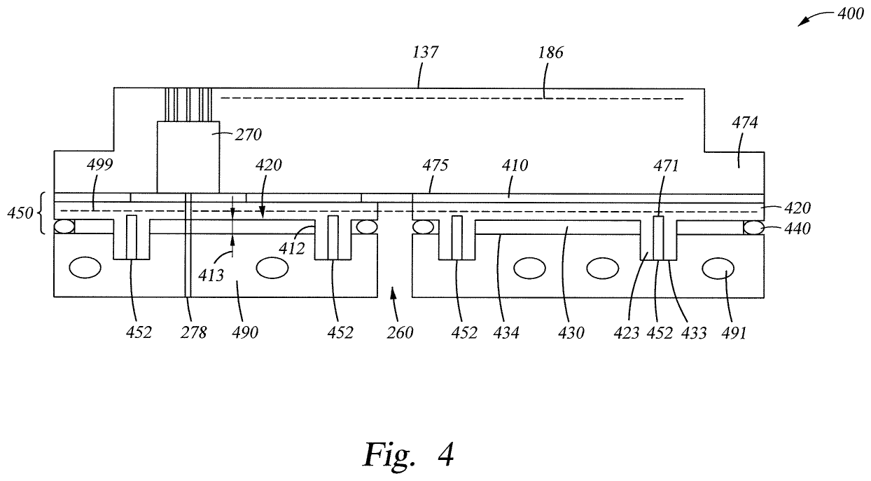

FIG. 4 is a schematic side view of the substrate support assembly 400 detailing yet another embodiment of the bonding layer 150 having metal therein disposed between a high power, high temperature electrostatic chuck (ESC) 474 and a cooling base 490 of the substrate support assembly 400. The heater 499 may be a multi-zone heater, for example four zones, suitable for heating the ESC 474 to a temperature of between about 150 Celsius and about 250 Celsius. The heater 499 may be disposed in the ESC 474. Alternately, the heater 499 may be disposed in a bonding layer 450 of the substrate support assembly 400.

The cooling base 490 has a top surface 434 and a plurality of cooling channels 491. The top surface 434 has a plurality of apertures 433 formed therein. The apertures 433 may be a continuous groove, for example in a circular pattern. Alternately, the apertures 433 may be discreet holes or slots formed in the cooling base 130. The apertures 433 are evenly radially spaced about a center (not shown) of the cooling base 490, such as at 120 degree increments, 90 degree increments, or other suitable angular increment providing equal spacing along a circular path defined at a radial distance from the center of the cooling base 490. In one embodiment, the apertures 433 are configured as a plurality of individual holes. The apertures 433 may be blind holes or thru-holes in the cooling base 490 and have spiral grooves suitable for accepting a fastener.

The bonding layer 450 may have a third layer 430, a second layer 420, and a first layer 410. The bonding layer 450 may additionally have one or more mechanical fasteners 452 passing therethrough. A plurality of O-rings 440 may provide a vacuum seal and protect the bonding layer 450.

The third layer 430 may be disposed on the top surface 434 of the cooling base 130. The third layer 430 may have a plurality of holes 412 formed therethrough. The plurality of holes 412 in the third layer 430 are configured to align with the apertures 433 in the cooling base 490. The third layer is configured as a thermal interface between the cooling base 490 and the second layer 420. The third layer 430 may be formed from polyimide (0.2 W/mk), flexible graphite (5 W/mk), perfluoropolymer, or other suitable material. The third layer 430 may have a thickness 343 between about 0.2 mm and about 2.0 mm.

The second layer 420 is disposed on the third layer 430 opposite the cooling base 490. The second layer 420 may be formed from a metal material. For example, the second layer 420 may be formed from molybdenum or an alloy thereof. The second layer 420 may have one or more heaters 499 disposed therein. The heaters 499 may provide a 4 zone heat source to the ESC 474 for maintaining the ESC 474 at a temperature between about 150 degrees Celsius and about 250 degrees Celsius.

The second layer 420 may have an appendage 423 extending therefrom. The appendage 423 is configured to extend into the apertures 433 of the cooling base 130. In the example, where the aperture 433 is a continuous groove, the appendage 423 may be a single continuous ring sized to fit in the groove. In the example where the aperture 433 is a plurality of holes, the appendage 423 may be shaped to fit into the holes, such as a square shape for a square hole like a mortise and tenon or a round shape for a round hole.

The appendage 423 may have an opening 471 formed therein. The appendage 423 may have a plurality of openings 471 in the example of a ring shaped appendage 423. The appendage 423 may have a single opening 471 such as when the appendage 423 is configured to fit in aperture 433 formed as a hole. The opening 471 is configured to accept a mechanical fastener 452 therein. The mechanical fastener 452 may be a bolt, a quick release fastener such as a quarter turn or keyed pin, or any other suitable device. After the appendage 423 is placed in the aperture 423, the mechanical fastener 452 may bind the two for securing the cooling base 130 to the second layer 420.

The first layer 410 is disposed on a bottom surface 475 of the ESC 474. The first layer 410 is bonded with the second layer 420. The first layer 410 may be formed from Al, Al₂O₃ or AlSiC, molybdenum alloy, AlSi alloy or aluminum alloy which is bonded to the ESC 474. The metal in the first layer 410 is configured to provide good thermal expansion and heat transfer between the ESC 474 and the cooling base 130. The first layer 410 may be formed by compressing a powder material at a very high pressure to make an alloy to increase strength, hardness, thermal conductivity and resistance to corrosion. The first layer 410 may be bonded to the ESC 474 and the second layer 420. In one embodiment, the first layer 410 is diffusion bonded to the ESC 474 and the second layer 420.

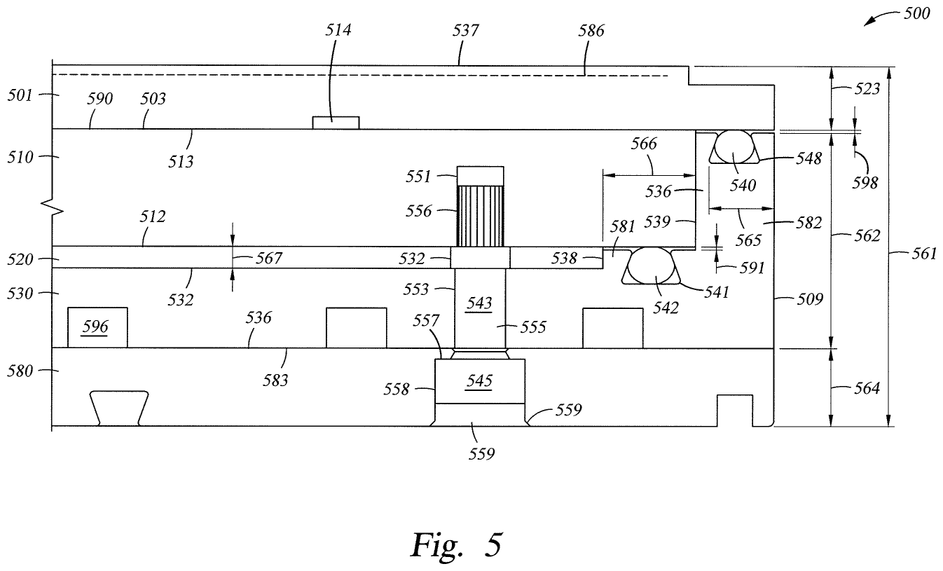

FIG. 5 is a schematic partial side view of the substrate support assembly 500 detailing yet another embodiment of a metal-containing layer bonding an electrostatic substrate support (ESC) 501 and a 530 cooling base. The substrate support assembly 500 has an outer circumference 509 and an overall height 561 of about 28 mm. The substrate support assembly 500 additionally has a second bonding layer 520 disposed below the metal base 510 and above the 530 cooling base. A facility plate 580 is disposed under the cooling base 530 in the substrate support assembly 500.

The ESC 501 has a top surface 537 and a bottom surface 503. A circumference of the ESC 501 is similar in dimensions to the outer circumference 509 of the substrate support assembly 500, i.e., the ESC 501 and substrate support assembly 500 have the same diameter. A resistive heater (not shown) and chucking electrode 586 is disposed therein the ESC 501. The resistive heaters operate to heat the ESC 501 over 200 degrees Celsius. A plurality of gas channels 514 is provided in the ESC 501 for supplying backside cooling gas to a substrate (not shown) disposed on the top surface 537. The ESC 501 may have a thickness of between about 5 mm and about 10 mm.

The metal bonding layer 590 may be disposed on the bottom of the ESC. The metal bonding layer 590 may have a thickness of between about 0.10 mm and about 0.50 mm. The metal bonding layer 590 may be formed from AlSiC, molybdenum, Al₂O₃, or other suitable metal. The metal bonding layer 590 may be adhered to the ESC 501 by diffusion or through other appropriate bonding techniques. In one embodiment, the metal bonding layer 610 is formed from molybdenum and has a coefficient of thermal expansion maybe about 4.8×10⁻⁶/C and a coefficient of thermal conductivity of about 138 W/mK.

A metal base 510 has a top surface 513, a bottom surface 512 and an outer circumference 539. The top surface 513 of the metal base 510 is disposed on the bottom surface 503 of the ESC 501. The metal base 510 may be about 9 mm thick and have a plurality of holes 551 disposed therein. The holes 551 may be threaded or otherwise configured to accept a fastener therein. The outer circumference 539 of the metal base 510 may be a first distance 565 smaller the outer circumference 509 of the substrate support assembly 500. The first distance 565, or difference in the radius of the circumferences 509, 539, may be between about 5 mm and about 10 mm.

The metal base 510 may be formed from AlSiC or other suitable metal. The metal base 510 may be adhered to the ESC 501 by diffusion or through other appropriate bonding techniques. The metal base 510 may have a coefficient of thermal expansion maybe about 6.8×10⁻⁶/C. The metal base 510 may have a coefficient of thermal conductivity selected in a range from about 180 W/mK to about 200 W/mK, such as about 190 W/mK.

A second bonding layer 520 is disposed below the metal base 510. The second bonding layer 520 may have a thickness 567 and a through hole 552 formed therethrough. The thickness 567 may be of less than about 2 mm. The through hole 552 may align with the hole 551 in the metal base 510. The second bonding layer 520 also has an outer perimeter 538. The outer perimeter 538 has a diameter smaller than a diameter of the outer circumference 539 of the metal base 510 by a second distance 566. The second distance 566, or differences in diameters, may be between about 5 mm and about 10 mm.

The second bonding layer 520 may be formed from a perfluoropolymer or other suitable material. The second bonding layer 520 may a coefficient of thermal expansion maybe about 1.2×10⁻⁶/C. The second bonding layer 520 may have a coefficient of thermal conductivity selected in a range from about 0.10 to about 0.20 W/mK, and in one exemplary embodiment, about 0.17 W/mK.

The cooling base 390 has a diameter substantially similar to the ESC 501. The cooling base has a top surface 532 and a bottom surface 536. The top surface 532 has a first step 581 extending thereabove and a second step 582 extending above the first step 581. The cooling base has a plurality of cooling channels 596 disposed therein and configured to flow a cooling fluid. The cooling base 530 additionally has a plurality of through holes 553.

The first step 581 may extend along the top surface 532 the second distance 566. The second distance 566 may be, as described above, between about 5 mm and about 10 mm. A gap 591 may be disposed between the top surface 532 at the first step 581 and the metal base 510. A groove 541 is formed in the first step 581. The groove 541 is configured to accept a gasket 542, such as an O-ring, therein. The gasket 542 provides a seal between the metal base 510 and the cooling base 530.

The second step 582 may extend the first distance 565 from the first step 581 to the outer circumference 509. The first distance 565 may be, as described above, between about 5 mm and about 10 mm. A gap 598 may be disposed between the top surface 532 at the second step 582 and the ESC 501. A groove 548 is formed in the top surface 532 at the second step 582. The groove 548 is configured to accept a gasket 540, such as an O-ring, therein. The gasket 540 provides a seal between the ESC 501 and the cooling base 530.

The cooling base 530 may be formed from an aluminum alloy, molybdenum, or other suitable material. In one embodiment, the cooling base 530 is formed from aluminum. The cooling base 530 has a thermal conductivity between about 151 W/(m·K) and about 202 W/(m·K) and linear thermal expansion coefficient of about 2.32×10−5 1/K.

The facility plate 580 is disposed below the cooling base 530 and attached thereto. The facility plate may have a thickness 564 of between about 3 mm and about 7 mm. The facility plate 580 may be formed from an aluminum alloy, molybdenum, or other suitable material. In one embodiment, the facility plate 580 is formed from aluminum. The facility plate 580 has a thermal conductivity between about 151 W/(m·K) and about 202 W/(m·K) and linear thermal expansion coefficient of about 2.32×10⁻⁵ 1/K.

The facility plate 580 has a plurality of holes 558 disposed therethrough. The holes 558 may have a shoulder 557 or a chamfer 559. The holes 558 in the facility plate 580 may align with the holes 553 in the cooling base 530, the second bonding layer 520 and the metal base 510. In this manner, the holes 558, 553,552, 551 are configured to accept a mechanical fastener 555 therein. The mechanical fastener 555 may have a head 545, a smooth shaft 543 and a threaded portion 556. The threaded portion 556 may be configured to mate and thread into the hole 551 in the metal base 510. The head 545 may be larger than the shaft 543 such that the head 545 does not precede past the shoulder 557 or interfaces with the chamfer 559. In this manner, the head 545 of the mechanical fastener 555 may draw the metal base 510, and the respective layers between, tight to the facility plate 580 for securing the substrate support assembly 500 together. An insulating plug 599 may be disposed in the holes 558 on the head 545. The insulating plug 599 prevents the mechanical fastener 555 from making electrical continuity from the metal base 510 through the facility plate 580 to portions of the substrate support assembly 500 disposed below the facility plate 580. In one embodiment, the plug is formed from polytetrafluoroethylene PTFE or other suitable material.

In one embodiment, the ESC 501 is formed from AlN and is bonded with a metal bonding layer 590 of molybdenum to the metal base 510 of AlSiC which is adhered by the second bonding layer 520 of perfluoro polymer to the cooling base 530 made of aluminum mechanically coupled to the facility plate 580. Advantageously, the substrate support assembly 500 can be made to withstand corrosive and high temperature environments while protecting the bonding layers holding the substrate support assembly 500 together.

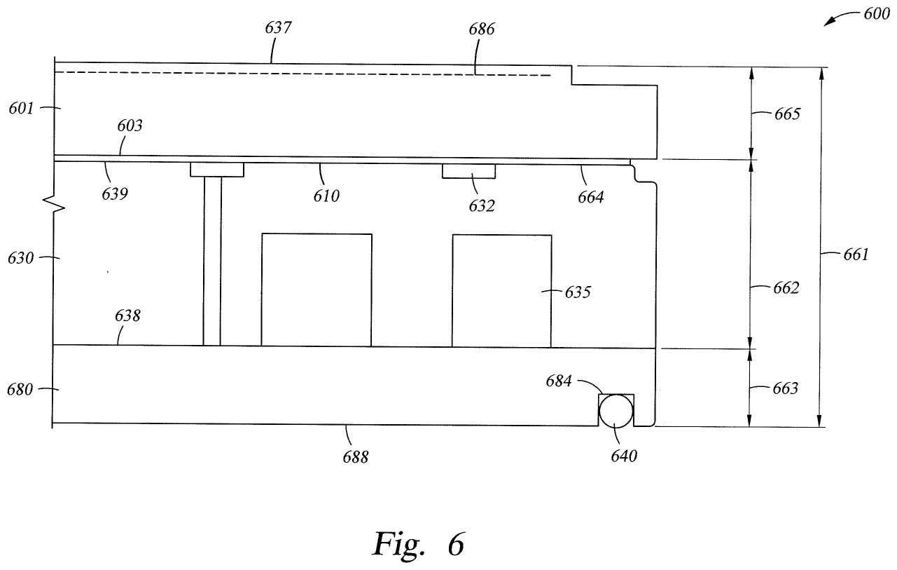

FIG. 6 is a schematic partial side view of the substrate support assembly 600 detailing yet another embodiment of a metal bonding layer 610 disposed between an electrostatic chuck (ESC) 601 and a cooling base 630. The substrate support assembly 600 is configured for providing high temperatures such as temperatures exceeding 200 degrees Celsius. The substrate support assembly additionally has a facility plate 680 upon which the cooling base 630 is bonded thereto.

The ESC 601 has a top surface 637 and a bottom surface 603. A circumference of the ESC 601 is substantially similar in diameter to an outer circumference for the substrate support assembly 600. A resistive heater (not shown) and chucking electrode 686 is disposed therein the ESC 601. The resistive heaters operate to heat the ESC 601 over 200 degrees Celsius. The ESC 601 may have a thickness 665 of between about 5 mm and about 10 mm.

The metal bonding layer 610 is disposed between the ESC 601 and the cooling base 630. The metal bonding layer 610 may have a thickness of between about 0.10 mm and about 0.50 mm. The metal bonding layer 610 may be formed from AlSiC, molybdenum, Al₂O₃, or other suitable metal. The metal bonding layer 610 may be adhered to the ESC 601 by diffusion or through other appropriate bonding techniques. In one embodiment, the metal bonding layer 610 is formed from molybdenum and has a coefficient of thermal expansion of about 4.8×10⁻⁶/C and a coefficient of thermal conductivity of about 138 W/mK.

The cooling base 630 has a top surface 639 and a bottom surface 638. The top surface 639 is disposed adjacent to the metal bonding layer 610 and may be bonded thereto. For example, the metal bonding layer 610 may be bonded by diffusion or other techniques to the top surface 639 of the cooling base 630. The top surface 639 may additionally have a plurality of gas channels 632 provided adjacent to the ESC 601 for supplying a gas for thermally controlling the ESC 601. The cooling base 630 may have additional cooling channels 635. The cooing channels 635 are configured to permit a cooling fluid to flow therethrough for maintaining the temperature of the cooling base 630.

The cooling base 630 may be formed from AlSiC, a composite thereof or other suitable material. The cooling base 630 may have a thickness of between about 15.0 mmm and about 19.0 mm. The cooling base 630 may a coefficient of thermal expansion maybe about 6.8×10⁻⁶/C. The cooling base 630 may have a coefficient of thermal conductivity selected in a range from about 170 W/mK to about 200 W/mK, such as about 190 W/mK. The thermal expansion can be further adjusted with the crystal structure of the aluminum matrix to raise thermal conductivity to as high as about 800 W/mK making the cooling base 630 a good heat sink.

A facility plate 680 may be disposed on the bottom surface 638 of the cooling base 630. The facility plate 680 has a bottom surface with a groove 684 disposed therein. The groove 684 is sized to accept a gasket 640, such as an O-ring, for creating a seal and maintaining the vacuum in the processing chamber in which the substrate support assembly 600 is disposed. The facility plate 680 may have a thickness 663 between about 3 mm and about 5 mm. The facility plate may be formed from molybdenum or other suitable material.

In one embodiment, the components of the substrate support assembly 600, i.e., ESC 601, a cooling base 630, and facility plate 680 described above, is diffusion bonded together. Advantageously, the metal material of the components allow a configuration of the substrate support assembly 600 which yields a minimal thickness while producing a lightweight and thermally responsive substrate support assembly 600. For example, an overall thickness 661 of the substrate support assembly 600 may be between about 24.0 mm and about 28.0 mm.

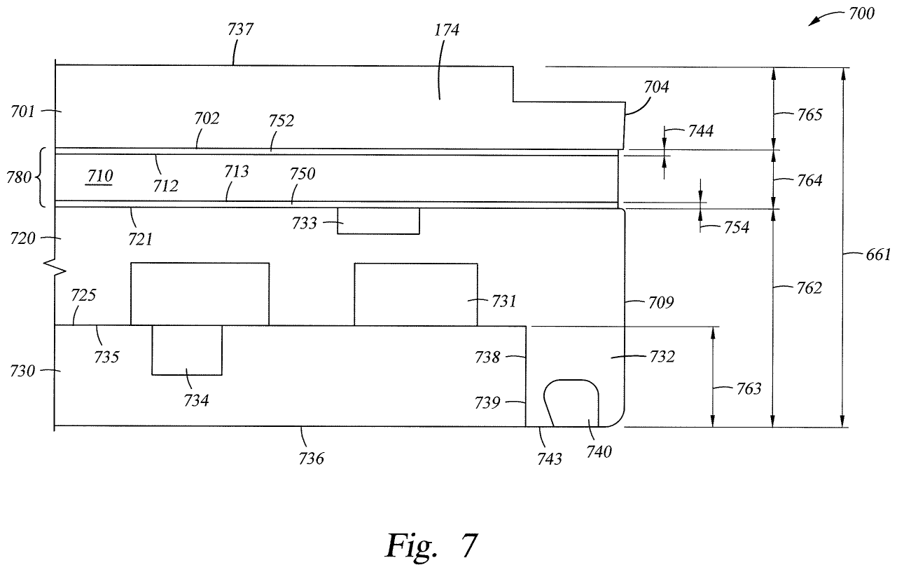

FIG. 7 is a schematic partial side view of the substrate support assembly 700 detailing yet another embodiment of a metal bonding layer 780 disposed between an electrostatic chuck (ESC) 701 and a cooling base 720. The substrate support assembly 700 is configured for providing high temperatures such as temperatures exceeding 200 degrees Celsius. The substrate support assembly 700 additionally has a second metal plate 730 upon which the cooling base 720 is bonded thereto.

The ESC 701 has a top surface 737 and a bottom surface 702. A circumference 704 of the ESC 701 is substantially similar in diameter to an outer circumference for the substrate support assembly 700. A resistive heater and chucking electrode (not shown) may be disposed in the ESC 701. The resistive heaters operate to heat the ESC 701 over 200 degrees Celsius. The ESC 701 may have a thickness 765 of between about 3 mm and about 7 mm. The ESC 701 may be formed from AlN, alumina or other suitable material.

The metal bonding layer 780 is bonded to the ESC 701 and the cooling base 720. The bond between the metal bonding layer 780 and both the ESC 701 and cooling base 720 may be formed under temperature and pressure to yield a bond wherein the atoms of the ESC 701 and cooling base 720 intersperse with the atoms of the metal bonding layer 780. The metal bonding layer 780 may have an overall thickness of about 2.0 mm to about 4.0 mm. The metal bonding layer 780 may be formed from several layers. For example, the metal bonding layer 780 may have a first metal-containing layer 752, a second metal-containing layer 710, and a third metal-containing layer 750.

The first metal-containing layer 752 may be disposed and in contact with the bottom surface 702 of the ESC 701. The first metal-containing layer 752 may be formed from a metal material such as molybdenum or other suitable metal. The first metal-containing layer 752 may have a thickness 744 of between about 0.10 mm and 0.30 mm.

The second metal-containing layer 710 may be disposed and in contact with the first metal-containing layer 752 on a surface opposite the ESC 701. The second metal-containing layer 710 may be formed from a metal material such as AlSiC, alumina or other suitable metal. The second metal-containing layer 710 may have a thickness of between about 2.0 mm and 4.0 mm.

The third metal-containing layer 750 may be disposed and in contact with the second metal-containing layer 710. The third metal-containing layer 750 may be formed from a metal material such as molybdenum or other suitable metal. The third metal-containing layer 750 may have a thickness 754 of between about 0.10 mm and 0.30 mm,.

The cooling base 720 has an outer circumference 709, a top surface 721 and a bottom surface 725. The top surface 721 of the cooling base 720 is disposed adjacent to the third metal-containing layer 750 of the metal bonding layer 780. The cooling base 720 additionally has one or more gas channels 733 disposed along the top surface 721 and one or more fluid channels 731 disposed along the bottom surface 725. The gas channels 733 and fluid channels 731 are configured for a cooling fluid to flow therethrough and maintain a temperature of the substrate support assembly 700. The cooling base 720 additionally has a step 732 protruding from the bottom surface 725. The step 732 may extend a distance 763 between about 3 mm and about 5 mm below the bottom surface 725. The step 732 may an inner wall 739 and a lower surface 743. The lower surface 743 being substantially parallel to the bottom surface 725. The step 732 has a groove 740 formed therein on the lower surface 743. The groove 740 is sized to accept a gasket for forming a seal for maintaining a vacuum in a processing chamber in which the substrate support assembly 700 may be disposed.

The second metal plate 730 has an outer wall 738, a top surface 735 and a bottom surface 736. The top surface 735 is disposed adjacent to the bottom surface 725 of the cooling base 720. The outer wall 738 of the second metal plate 730 is disposed adjacent to the inner wall 739 of the cooling base 720. Additionally, the bottom surface 736 of the second metal plate 730 is substantially coplanar to the lower surface 743 of the step 732. Thus, the second metal plate 730 fits into an area bounded by the cooling base 720. The second metal plate 730 has fluid channels 734 fluidly connected to the fluid channels 731 of the cooling base 720 for transporting cooling fluid thereto. The second metal plate 730 may be formed from molybdenum or other suitable material and have a thickness of between about 3 mm and about 5 mm.

The substrate support assembly 700 may thus be configured in a thin configuration, i.e., about 21.5 mm from top to bottom, at a weight of only about 21 pounds while still providing strong bonds between the various components, such as the ESC 701 and cooling base 720 therein, while thermally controlling the temperature of a substrate thereon. Thus, substrate support assembly 700 advantageously provides a lightweight and compact configuration which is suitable for holding a substrate thereon during high energy plasma processing.

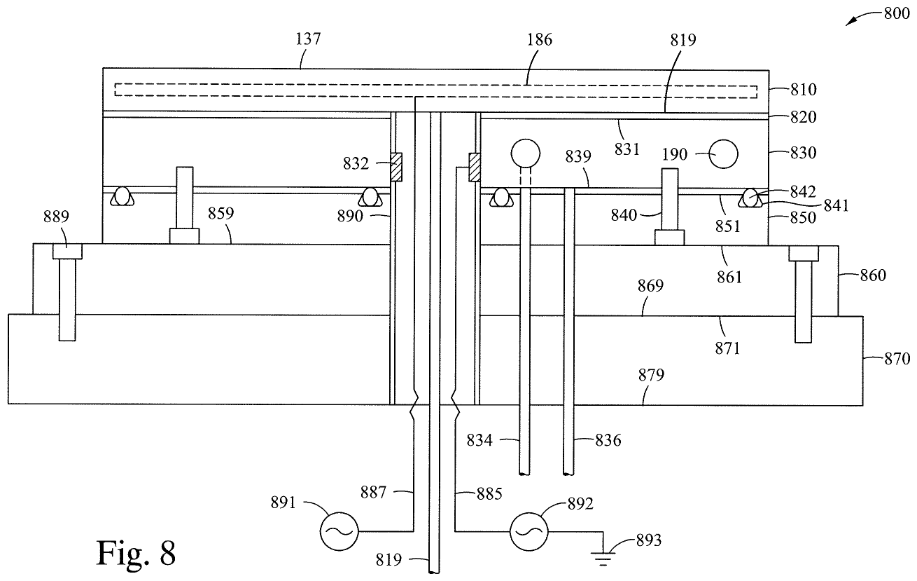

FIG. 8 is a schematic partial side view of the substrate support assembly 800 detailing yet another embodiment of a metal-containing layer bonding an electrostatic substrate support (ESC) 810 to a powered cooling base 830. The ESC 810 may be disposed on the powered cooling base 830. The powered cooling base 830 may be disposed on a facility plate 850. The facility plate 850 may be disposed on an insulated layer 860 disposed atop a mounting base 870. The mounting base 870 may formed from aluminum, aluminum alloy or other suitable material. The ESC 810, powered cooling base 830, facility plate 850, insulated layer 860 and mounting base 870 may be coupled together in forming the substrate support assembly 800.

The ESC 810 may be a high power chuck with or without. The ESC 810 has a body having a workpiece support surface 137, and a bottom surface 819. The chucking electrode 186 is disposed in the body. One or more heaters may optionally be disposed in the body. The chucking electrode 186 is directly coupled by an electrical connection 887 to a chucking power source 891. The chucking electrode 186 may be energized with a direct current between about +/−0 KV and about +/−7 KV, such as about +/−3.5 KV.

A first bonding layer 820 may be formed between the powered cooling base 830 and the bottom surface 819 of the ESC 810. The first bonding layer 820 may be formed from Al, Al₂O₃ or AlSiC, i.e., a metal containing layer. The first bonding layer 820 may have a thickness extending perpendicularly between the ESC 810 and the powered cooling base 830. The thickness may be between about 0.2 inches and about 0.1 inches.

The powered cooling base 830 has a top surface 831 and a bottom surface 839. The top surface 831 is in contact with the first bonding payer 820. The powered cooling base 830 is formed from a metal material or other suitable material. For example, the powered cooling base 830 may be formed from aluminum (Al), aluminum alloy or molybdenum. The powered cooling base 830 includes cooling channels 190 formed therein. The cooling channels 190 are connected to a heat transfer fluid source 834 and a heat transfer fluid return 836. The heat transfer fluid source 834 provides a heat transfer fluid, such as a liquid, gas or combination thereof, which is circulated through one or more cooling channels 190 disposed in the powered cooling base 830. The fluid flowing through neighboring cooling channels 190 may be isolated to enabling local control of the heat transfer between the ESC 810 and different regions of the powered cooling base 830, which assists in controlling the lateral temperature profile of the substrate 124. In one embodiment, the heat transfer fluid circulating through the cooling channels 190 of the powered cooling base 830 maintains the powered cooling base 830 at a temperature between about 90 degrees Celsius and about 80 degrees Celsius or at a temperature lower than 90 degrees Celsius.

The powered cooling base 830 is electrically coupled to a cooling electrical connection 835 through to an electrical connector 832. The cooling electrical connection 835 is coupled to a second power source 892 and ground 893. The second power source 892 may be energized the powered cooling base 830 with a direct current between about +/−0 KV and about +/−7 KV, such as about +/−3.5 KV.

The facility plate 850 has a top surface 851 and a bottom surface 859. The top surface 851 of the facility plate 850 is disposed below the powered cooling base 830 and attached thereto. The facility plate 850 may have a thickness of between about 3 mm and about 7 mm. The facility plate 580 may be formed from a single crystal or polycrystalline ceramic material such as aluminum nitride (AlN), silicon carbide (SiC) or other suitable material. In one embodiment, the facility plate 850 is formed from AlN. The facility plate 850 has a thermal conductivity between about 170 W/(m·K) and about 220 W/(m·K) and linear thermal expansion coefficient of between about 4.2×10⁻⁶ 1/C and about 4.6×10⁻⁶ 1/C. The facility plate 850 has a plurality of holes disposed therethrough which provide for connections to the powered cooling base 830. For example, the fluid source 834 and fluid return 836 may traverse through one or more holes in the facility plate 850. Additionally, a RF ground tube 890 may be provided through one hole in the facility plate 850.

A plurality of mechanical fasteners 840 couple the powered cooling base 830 to the facility plate 850. The facility plate 850 includes stepped through hole extending from the bottom surface 859 to the top surface 851. A receiving socket is disposed in the bottom surface 839 of the powered cooling base 830. The stepped through hole is configured to accept the mechanical fasteners 840. The mechanical fasteners 840 extend through the through hole and mates with the receiving socket disposed in the powered cooling base 830. In one embodiment, one or more mechanical fasteners 840 are a threaded fastener and the receiving socket is a tapped hole or threaded insert, such as a HELICOIL® type threaded insert. Alternately, the mechanical fasteners 840 may be a bolt, a press fit pin, a rivet, or other suitable fastener. One or more seals 842 may be disposed in a seal groove 841 in the facility plate 850. The mechanical fasteners compress the seals 842 between the powered cooling base 830 and the facility plate 850 to make an airtight seal therebetween. The mechanical fasteners 840 ensure the connection between the powered cooling base 830 and the facility plate 850 is secure yet removable.

The insulated layer 860 has a top surface 861 and a bottom surface 869. The bottom surface 859 of the facility plate 850 is disposed on the top surface 861 of the insulated layer 860. The insulated layer 860 may be a thermoset, rigid and translucent plastic. The insulated layer 860 is formed from a polystyrene material, such as a polyimide material, a high-performance polyimide-based plastic, or polystyrene cross linked with divinylbenzene, or other suitable plastic such as polytetrafluoroethylene PTFE. The insulated layer 860 has a thermal coefficient of expansion between about 3.0×10⁻⁵/C and about 5×10⁻⁵/C. The insulated layer 860 has a thermal conductivity of about 0.2 W/mK to about 1.8 W/mK. In one embodiment, the insulated layer 860 is formed from polystyrene cross linked with divinylbenzene.

The insulated layer 860 may include a receiving hole suitable for a mechanical fastener 889 which mates with a receiving socket disposed in the mounting base 870. In one embodiment, the mechanical fastener 889 is a threaded fastener and the receiving socket is a tapped hole or threaded insert, such as a HELICOIL® type threaded insert. Alternately, the mechanical fastener 889 may be a bolt, a press fit pin, a rivet, or other suitable fastener. The mechanical fastener 889 ensures the connection between the insulated layer 860 and the mounting base 870 is secure yet removable.

The RF ground tube 890 has a plurality of electrical and fluid connections, such as a backside gas supply line 819, disposed therethrough. For example, the electrical connection 887 coupled to the chucking power source 891 and the cooling electrical connection 835 coupled to the second power source 892 is disposed therein the RF ground tube 890 to protect the electrical connections from coupling with RF energy in the processing chamber.

In one embodiment, the substrate support assembly 800 provides about 7 KV of chucking voltage to hold a substrate to the workpiece support surface 137 of the ESC 810. The 7 KV of chucking voltage is provided equally from the chucking power source 891 and second power source 892 electrically coupled to the powered 830. For example, the chucking power source 891 may provide 3.6 KV of DC chucking voltage and the second power source 892 may provide −3.6 KV of DC chucking voltage to provide a total of 7 KV of chucking voltage to chuck the substrate to the workpiece support surface 137 of the ESC 810. Advantageously, a lower DC power supply may be used to generate a high chucking voltage.

In the various embodiments described above, the substrate support assemblies had an electrostatic chuck bonded to a cooling base by a bonding layer containing a metal. The bonding layer in some of the embodiments was formed from several distinct layers that enable operation of the electrostatic chuck at a range of temperatures wherein at least one of the distinct layers is a metal. The function of the metal in the bonding layer varies for low temperature and high temperature configurations of the electrostatic chuck. The metal bond for the low temperature configuration provides good heat transfer from the ceramic electrostatic chuck to the cooling base disposed thereunder. The metal bond for the high temperature configuration allows the cooling base to be mechanically attached to a metal bonded plate under the ceramic electrostatic chuck while a thermal gasket is utilized between a molybdenum layer and the cooling plate for handling the temperature drop therebetween. Advantageously, the metal in the bonding layer provides the ability to attached the electrostatic chuck to the cooling base in a manner that provides good thermally conductivity along with a strong solid connection. This in turn provides better temperature control and uniformity for the electrostatic chuck and minimizes damage due to heat induced stress at adjoining locations having dissimilar thermal expansion due to temperature gradients. Thus, the metal in the substrate support assembly bonding layer provides good heat transfer and longevity to the substrate support assembly.

While the foregoing is directed to implementations of the present invention, other and further implementations of the invention may be devised without departing from the basic scope thereof, and the scope thereof is determined by the claims that follow.

1. A substrate support assembly, comprising:
an electrostatic chuck having a workpiece supporting surface and a bottom surface;
a cooling base having a top surface; and
a first bonding layer securing the bottom surface of the electrostatic chuck and the top surface of the cooling base, wherein the first bonding layer comprises a metal layer.

2. The substrate support assembly of claim 1, wherein the first bonding layer further comprises:
a first layer; and
a second layer comprising the metal-containing layer.

3. The substrate support assembly of claim 2, wherein the first bonding layer further comprises:
a third layer disposed below the second layer and bonded to the cooling base.

4. The substrate support assembly of claim 2, wherein the first bonding layer has an operating temperature that includes temperatures between about 150 degrees Celsius and about 200 degrees Celsius.

5. The substrate support assembly of claim 1, further comprising:
a plastic base disposed below the cooling base; and
a second bonding layer disposed between the cooling base and the plastic base, wherein a thermal conductivity of the second bonding layer is about 0.2 W/mK.

6. The substrate support assembly of claim 1, further comprising:
a mechanical fastener connecting the first bonding layer and the cooling base.

7. The substrate support assembly of claim 1, wherein the first layer first bonding layer is comprised of a perfluoro compound.

8. The substrate support assembly of claim 7, wherein a thickness of the first bonding layer is between about 0.3 mm and about 5 mm.

9. The substrate support assembly of claim 1, wherein the first bonding layer comprises polyimide or silicone.

10. The substrate support assembly of claim 9, wherein the third layer comprises molybdenum.

11. The substrate support assembly of claim 1 further comprising:
an o-ring providing a seal between the electrostatic chuck and the cooling base, the o-ring circumscribing the first bonding layer.

12. The substrate support assembly of claim 3, wherein a coefficient of thermal expansion for the first layer is greater than that of the second layer or the third layer.

13. The substrate support assembly of claim 1 wherein the first bonding layer has a heater disposed therein.

14. A processing chamber comprising:
a body having walls and a lid defining an interior processing region;
a substrate support assembly disposed in the interior processing region, the substrate support assembly comprising:
an electrostatic chuck having a workpiece supporting surface and a bottom surface;
a cooling base having a top surface; and
a first bonding layer securing the bottom surface of the electrostatic chuck and the top surface of the cooling base, wherein the first bonding layer comprises a metal-containing layer.

15. The processing chamber of claim 14, wherein the first bonding layer further comprises:
a first layer; and
a second layer comprising the metal-containing layer.

16. The processing chamber of claim 15, wherein the first bonding layer further comprises:
a third layer disposed below the second layer and bonded to the cooling base.

17. The processing chamber of claim 14, wherein the substrate support assembly further comprises:
a plastic base disposed below the cooling base; and.

18. The processing chamber of claim 14, wherein the substrate support assembly further comprises:
a mechanical fastener connecting the first bonding layer and the cooling base.

19. The processing chamber of claim 14, wherein the first bonding layer has a heater disposed therein.

20. The processing chamber of claim 16, wherein the first layer comprises polyimide or silicone, the second layer is AlSiC or molybdenum, and the third layer comprises molybdenum.

21. A substrate support assembly, comprising:
an electrostatic chuck having a workpiece supporting surface, a bottom surface and a dielectic body, the dielectric body having a chucking electrode disposed therein;
a cooling base having a top surface;
a first bonding layer securing the bottom surface of the electrostatic chuck and the top surface of the cooling base, wherein the first bonding layer comprises a metal layer; and
a RF grounding tube, wherein a first electrical connection from a power source is disposed therethrough and couples a chucking power supply to the chucking electrode, and a second electrical connection coupling the cooling base to a second power source, wherein a chucking power of a substrate disposed on the workpiece supporting surface is split equally between the first power source and the second power source.
